(19) United States
(12) Patent Application Publication
(10) Pub. No.: US 2026/0016757 A1
(43) Pub. Date: Jan. 15, 2026

(54) CONTROL METHOD AND CONTROL SYSTEM FOR CONTROLLING A POSITION OF AN OBJECT WITH AN ELECTROMAGNETIC ACTUATOR

(71) Applicant: ASML Netherlands B.V., Veldhoven (NL)

(72) Inventors: Hans BUTLER, Best (NL); Marinus Engelbertus Cornelis MUTSAERS, Rijen (NL); Noah TABOR, Eindhoven (NL)

(73) Assignee: ASML Netherlands B.V., Veldhoven (NL)

(21) Appl. No.: 18/875,576

(22) PCT Filed: May 26, 2023
(86) PCT No.: PCT/EP2023/064215

§ 371 Date: Dec. 16, 2024

(30) Foreign Application Priority Data
Jun. 21, 2022 (EP) 22180029.5

(51) Int. Cl. G03F 7/00; G02B 26/08

(52) U.S. Cl. CPC G03F 7/70266; G02B 26/0816; G03F 7/70591

(57) ABSTRACT

A control method is provided for controlling a position of an object with an electromagnetic actuator. The, method comprises at least the following operations. Determining a position control error between a desired position and an actual position of the object. Determining a feedback control signal based on the position control error. Determining a feedforward control signal based on the desired position. Combining the feedback control signal and the feedforward control signal into an actuator input. Determining an actuator gain correction based on the actuator input and the actual position of the object. Applying the actuator gain correction to the actuator input to provide a corrected actuator input. Feeding the corrected actuator input to the electromagnetic actuator to exert an actuator force on the object.

### FIELD

The present invention relates to a control method for controlling a position of an object using an electromagnetic actuator and a control system to control the position of an object. The invention further relates to a lithographic apparatus comprising such control system.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

In known embodiments of a lithographic apparatus, a projection system with one or more mirrors may be provided. To accurately position the mirrors, for example to counteract vibrations, the mirror may be position controlled. Such a position controlled mirror may be actively controlled in a control system comprising a feedforward controller and a feedback controller. An electromagnetic actuator may be used to exert an actuation force on the mirror based on control signals provided by the feedforward controller and the feedback controller.

The behavior of an electromagnetic actuator, e.g. a force provided by the electromagnetic actuator as function of current that is fed into the electromagnetic actuator may depend on the actual actuator position with respect to a reference, for example a reference frame. Therefore, the properties of each electromagnetic actuator are calibrated before use. During calibration of the electromagnetic actuator, non-linearities in the behavior of the electromagnetic actuator may be determined for different positions of the electromagnetic actuator. On the basis of the determined behavior, non-linear compensation as function of input current and actual actuator position may be applied in the control system to provide adjusted current input signals to the electromagnetic actuator.

However, due to slow changes in variables over time, such as reference drift, and slow aging of magnets, the non-linearity correction obtained by calibration may, after a certain time period, not be accurate anymore leading to changes in offset current. In particular, when the non-linearity calibration cannot be performed in the machine, any unknown changes over time cannot be compensated. In practice, this may be solved partly by in-machine local actuator gain calibrations at multiple positions, but this takes a significant amount of time.

Further, the calibration accuracy of the electromagnetic actuator is limited. This accuracy may not be sufficient to meet present accuracy specifications. Moreover, in the future, higher accelerations of the mirrors may be required, which may even increase the accuracy specifications for the electromagnetic actuators.

### SUMMARY

It is an object of the invention to provide a control method for controlling a position of an object using an electromagnetic actuator that is capable of providing an increased accuracy in positioning of the object. In particular, it is an object of the invention to provide a control method for controlling a position of an object using an electromagnetic actuator, which control method takes into account drift in the behavior of the electromagnetic actuator. Further, it is an object of the invention to provide a control system to control the position of an object, for example a mirror of a projection system of a lithographic apparatus, wherein the control system is arranged to provide an increased accuracy in positioning of the object. In particular, the control system may take into account drift in the behavior of the electromagnetic actuator.

According to an aspect the invention there is provided a control method for controlling a position of an object with an electromagnetic actuator, the method comprising:
determining a position control error between a desired position and an actual position of the object,
determining a feedback control signal based on the position control error,
determining a feedforward control signal based on the desired position,
combining the feedback control signal and the feedforward control signal into an actuator input,
determining an actuator gain correction based on the actuator input and the actual position of the object,
applying the actuator gain correction to the actuator input to provide a corrected actuator input, and
feeding the corrected actuator input to the electromagnetic actuator to exert an actuator force on the object.

According to an aspect the invention there is provided a control system to control the position of an object, wherein the control system comprises:
an electromagnetic actuator arranged to exert an actuator force on the object based on an actuator input,
a feedback control device arranged to provide a feedback control signal based on a position control error between a desired position and an actual position of the object,
a feedforward control device arranged to provide a feedforward control signal based on the desired position,
wherein the control system is arranged to combine the feedback control signal and the feedforward control signal into an actuator input,
wherein the control system comprises an actuator gain correction device, wherein the actuator gain correction device is arranged to determine an actuator gain correction based on the actuator input and the actual position of the object, and arranged to apply the actuator gain correction to the actuator input to provide a corrected actuator input to the electromagnetic actuator.

According to an aspect the invention there is provided a lithographic apparatus comprising such control system to control the position of an object of the lithographic apparatus.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and a radiation source;

FIG. 2 depicts in more detail a part of the lithographic system of FIG. 1;

FIG. 3 depicts a control scheme of a control system for a mirror of a projection system;

FIG. 4 depicts a control scheme of a control system for a mirror of a projection system comprising an actuator gain correction device;

FIG. 5 depicts in more detail the actuator gain correction device of FIG. 4;

FIG. 6 depicts an alternative embodiment of a control scheme of a control system for a mirror of a projection system comprising an actuator gain correction device;

FIG. 7 depicts in more detail the actuator gain correction device of FIG. 6; and

FIG. 8 depicts a further alternative embodiment of a control scheme of a control system for a mirror of a projection system comprising an actuator gain correction device.

### DETAILED DESCRIPTION

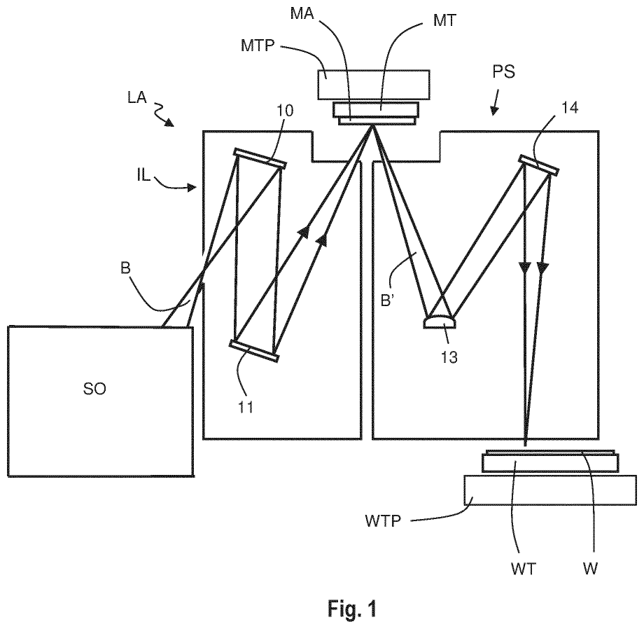

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

A substrate table positioning system WTP is provided to position the substrate table WT in a desired position. The substrate positioning system WTP comprises a position measurement system to measure a position of the substrate table WT and an actuation system to move the substrate table WT to a desired position. A patterning device support positioning system MTP is provided to position the support structure MT in a desired position. The patterning device support positioning system MTP also comprises a position measurement system to measure a position of the support structure MT and an actuation system to move the support structure MT to a desired position.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13, 14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO may be a laser produced plasma (LPP) source, a discharge produced plasma (DPP) source, a free electron laser (FEL) or any other radiation source that is capable of generating EUV radiation.

The lithographic process comprises a series of projection phases, in which the patterned EUV radiation beam B′ is projected onto the substrate W (exposure phase) and/or in which the substrate W is being aligned with the patterned EUV radiation beam B′ (alignment phase) and idle phases in which no patterned EUV radiation beam B′ is projected onto the substrate W, or on a non-relevant part of the substrate W and positioning accuracy of the substrate W with respect to the patterned EUV radiation beam B′ is less critical. During the projection phase the patterning device and the substrate may be moved in a scanning movement with a constant scanning velocity. The idle phase may be used to decelerate and (re)accelerate the patterning device MT and the substrate W to the desired scanning velocity and a desired alignment with respect to the EUV radiation beam B and the patterned EUV radiation beam B′, respectively. The constant scanning velocity of the patterning device MT is typically different than the constant scanning velocity of the substrate W.

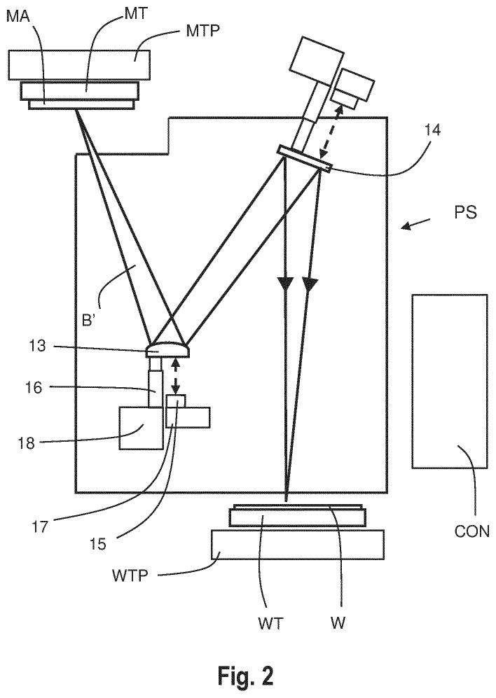

FIG. 2 shows in more detail the projection system PS of the lithographic apparatus of FIG. 1. The projection system PS comprises mirrors 13, 14, hereinafter referred to as first mirror 13 and second mirror 14. The first mirror 13 and the second mirror 14 are position controlled mirrors. This means that a position of the first mirror 13 is controlled in a first range of movement and a position of the second mirror 14 is controlled in a second range of movement.

A first position measurement system 15 is provided to measure an actual position of the first mirror 13 with respect to a reference frame 17, e.g. a sensor frame. The position measurement system 15 is for example an interferometer position measurement system. A control unit CON is provided to control the position of the first mirror 13 with respect to the reference frame 17. On the basis of an output signal of the control unit CON, electromagnetic actuators 16, e.g. Lorentz actuators, are used to position the first mirror 13 in the desired position with respect to the reference frame 17. In the shown embodiment, the electromagnetic actuators 16 are mounted on a force frame 18. The position of the force frame 18 may change, for example drift with respect to the position of the reference frame 17.

The control unit CON, the position measurement system 15 and the electromagnetic actuators 16 form a control system arranged to control the position of the first mirror 13 in multiple, e.g. six. degrees of freedom.

Correspondingly, to control the position of the second mirror 14 and any further position controlled mirror of the projection system PS, a further position measurement system may be provided for the second mirror 14 and each further mirror to measure the position of the respective mirror. The control unit CON may comprise a control loop to control the position of the second mirror 14 and any further mirror. The control unit CON may provide output signals to respective actuators to position the second and any further mirror in the desired position.

The control unit CON is depicted as a single unit for controlling the position of the first mirror 13, the second mirror 14 and any further mirror. This control unit CON may for example be integrated in a central processing device of the lithographic apparatus LA or a separate control unit of the projection system PS.

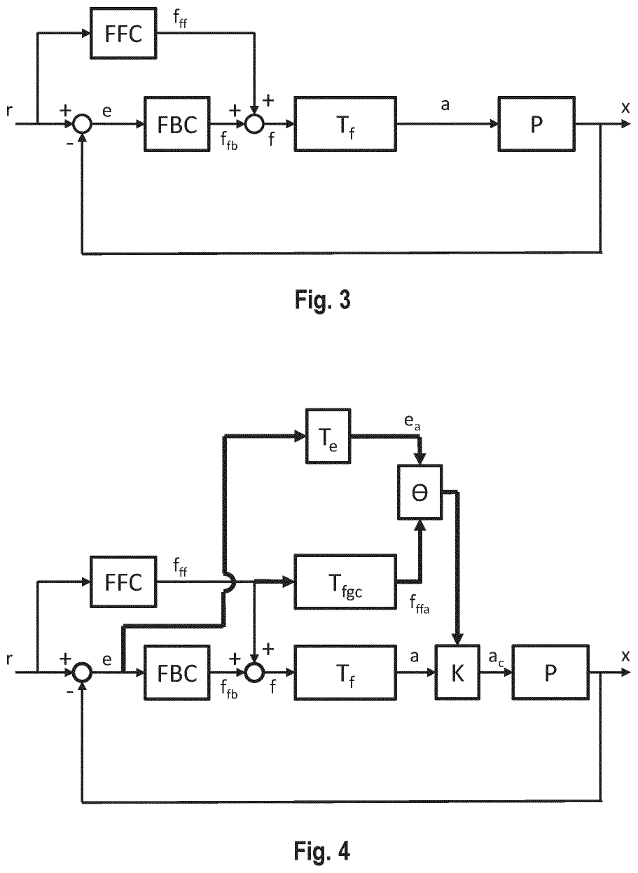

FIG. 3 shows a control scheme of a control system controlling a position of the first mirror 13 in six degrees of freedom using electromagnetic actuators 16. Block P represents the electromagnetic actuators 16, the first mirror 13 and the position measurement system 15, as shown in FIG. 2. The input of the block P is an actuator input fed to the electromagnetic actuators 16 and the output of the block P is the actual position x of the first mirror 13 measured by the position measurement system 15.

The actual position x of the first mirror 13 may be compared at a comparing device with a desired position r of the first mirror 13 to obtain a position control error e. The desired position may be provided by a setpoint-generator. The position control error e is fed into a feedback control device FBC, for example a PID controller, to obtain a feedback control signal f_{fb}. In addition, the desired position r is fed into a feedforward control device FFC. On the basis of the desired position r, the feedforward control device FFC provides a feedforward control signal f_{ff}.

The feedback control signal f_{fb} and the feedforward control signal f_{ff} are combined in a control signal and fed into a decoupling device T_{f} to transform the control signal f in control coordinates into an actuator input a in actuator coordinates. The decoupling device T_{f} is a two-step decoupling system containing gain balancing and gain scheduling steps.

The gain balancing and gain scheduling steps provide a transformation of the control signal, e.g. current setpoints for the electromagnetic actuators 16, using e.g. a nonlinear function of the motor constant compensation, resulting into desired actuator forces.

In an embodiment gain balancing and gain scheduling steps may for example apply a series of linear controllers, wherein each of the linear controllers is arranged to provide a specific control for a different operating point of the system, e.g. a position of the electromagnetic actuator 16. On the basis of one or more scheduling variables, the actual operating region of the electromagnetic actuator may be determined, and the associated linear controller may be selected to provide the respective control signal. In an alternative embodiment multi position gain balancing may be extended with specific filtering to cope with position dependency.

The actuator input a is fed into the electromagnetic actuator 16 to move the first mirror 13 towards the desired position.

The control system shown in FIG. 3 may be suitable to control the position of a well calibrated electromagnetic actuator 16. The calibration data of a calibration of the electromagnetic actuator 16 may be included in the transformation of the control signal f into the actuator input as applied by the decoupling device T_{f}.

However, due to slow change in variables over time, such as reference drift, and slow aging of magnets, the non-linearity correction obtained by calibration may, in the course of time, not be accurate anymore leading to changes in offset current. In particular, when the non-linearity calibration cannot be performed in the machine, any unknown changes over time cannot be compensated. In practice, this may be solved partly by in-machine local actuator gain calibrations at multiple positions, but this takes a significant amount of time, which is generally undesirable.

FIG. 4 shows an embodiment of a control scheme of a control system comprising an actuator gain correction device arranged to take into account these slow changes in variables over time by applying an actuator gain correction K to the actuator signal a. The actuator gain correction K applied to the actuator input a is indicated by block K in FIG. 4 and provides a corrected actuator input a_{c} that is fed to the respective electromagnetic actuator 16.

In the actuator gain correction device, the actuator gain correction K is calculated on the basis of the feedforward control signal f_{ff} and the position control error e.

The actuator gain correction device comprises a decoupling device T_{fge}, a transformation matrix device Tₑ, and a gain correction calculation device ⊖ and a gain correction block K that is provided to apply the actuator gain correction K to the actuator input a to obtain the corrected actuator input a_{c}.

The feedforward control signal f_{ff} is fed into the decoupling device T_{fgc} to transform the feedforward control signal f_{ff} in control coordinates into a feedforward control signal f_{ffa} in actuator coordinates. The decoupling device T_{fgc} applies the same transformation as the decoupling device T_{f} of the main control loop, i.e. the decoupling device T_{fgc} is a two-step decoupling system containing the same decoupling steps as the decoupling device T_{f}.

Thus, the feedforward control signal f_{ffa} in actuator coordinates may be determined as:

$${f}_{ffa} = {T}_{fgc} \cdot {f}_{ff} ,$$

wherein T_{fgc} is a force transformation matrix from feedforward force in control coordinates to actuator coordinates, and f_{ff} is the feedforward control signal.

The position control error e is fed into a transformation matrix device Tₑ to transform the position control error e in control coordinates into a position control error eₐ in actuator coordinates.

The position control error eₐ in actuator coordinates can be determined as:

$${e}_{a} = {T}_{e} \cdot e ,$$

wherein Tₑ is a position transformation matrix from object position coordinates to actuator coordinates, and e is the position control error.

In the gain correction calculation device ⊖, a value of the actuator gain correction K is determined on the basis of the position control error eₐ in actuator coordinates and the feedforward control signal f_{ffa} in actuator coordinates. The actuator gain correction K may for example be calculated as follows:

$$K = - Γ \int ( {p}_{11} {e}_{a} ( t ) + {p}_{12} \frac{{de}_{a} ( t )}{dt} ) {f}_{ffa} ( t ) dt$$

wherein K is the actuator gain correction, p₁₁ is a first constant, eₐ is the position control error in actuator coordinates, p₁₂ is a second constant, and f_{ffa} a feedforward control signal in actuator coordinates.

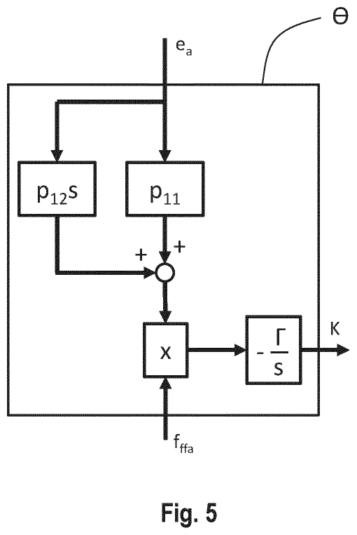

FIG. 5 shows the calculation of the actuator gain correction K in the gain correction calculation device ⊖ in a block scheme. The constants may have any suitable value that ensures that the actuator gain correction device is stable. Advantageously, the first constant p11 may be selected to be substantially equal to a proportional control constant of the feedback control device FBC and the second constant p12 may be selected to be substantially equal to a derivative control constant of the feedback control device FBC. The term

$${p}_{11} {e}_{a} ( t ) + {p}_{12} \frac{{de}_{a} ( t )}{dt}$$

may already, or at least partially, be calculated in the feedback control device FBC and can be taken directly from the feedback control device FBC.

The calculated gain correction K is applied in block K of the main control scheme to adjust the actuator input a into a corrected actuator input a_{c} which corrected actuator input a_{c} takes into account slow changes in variables over time that have effect on the behavior of the electromagnetic actuators, such as reference drift, and slow aging of gravity compensator magnets.

Since the gain correction K is calculated in actuator coordinates only 6 compensation parameters have to be calculated for a position control system configured to control the position in six degrees of freedom. In this way appropriate compensation can be efficiently obtained in an efficient calculation.

It is noted that, generally, an adaptive scheme as shown in FIG. 5 may be sensitive for noise due to the multiplication x of the position control error eₐ and the feedforward control signal f_{ffa} that may have coherent noise contributions. However, by using the noise-free feedforward control signal f_{ffa} this problem is avoided in this adaptive scheme.

Further, in the actuator gain correction device shown in FIGS. 4 and 5, the position control error eₐ in actuator coordinates and the feedforward control signal f_{ffa} in actuator coordinates are used to calculate the actuator gain correction K. In addition or as an alternative, parameters based on the position control error eₐ and the feedforward control signal f_{ffa} such as filtered values, derivative values, integrated values, and/or combinations thereof, may be used to calculate the actuator gain correction K.

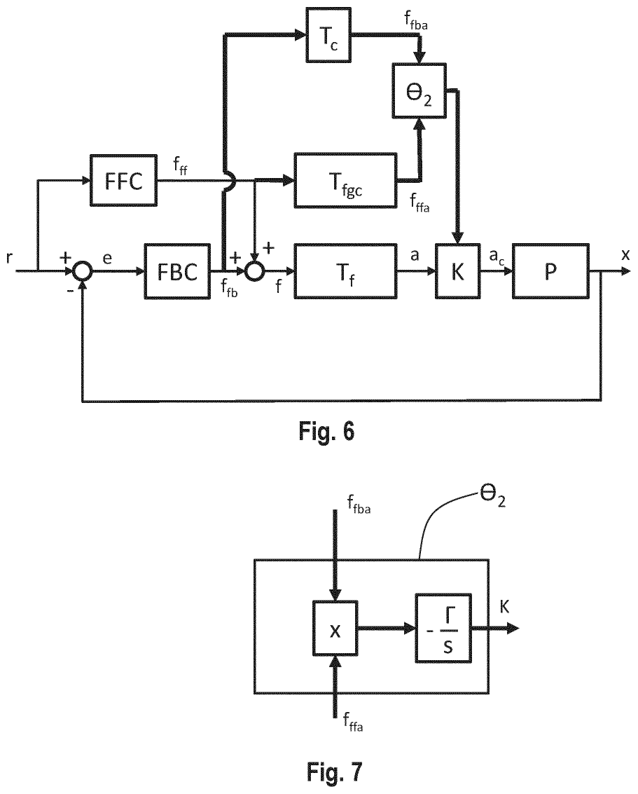

FIG. 6 shows an alternative control scheme having an actuator gain correction device to apply a gain correction K on the actuator input a of the electromagnetic actuators of the control system. The main control scheme corresponds to the control scheme of FIG. 3. In the actuator gain correction device of FIG. 6, a gain correction K is determined on the basis of the feedforward control signal f_{ff} and the feedback control signal f_{ff}.

The feedforward control signal f_{ff} is fed into the decoupling device T_{fgc} to transform the feedforward control signal f_{ff} in control coordinates into a feedforward control signal f_{ffa} in actuator coordinates. T_{f} and T_{fgc} apply the same decoupling steps. The feedback control signal f_{fb} is fed into a transformation matrix device Tₑ to transform the feedback control signal f_{fb} in control coordinates into a feedback control signal f_{fba} in actuator coordinates.

The feedforward control signal f_{ffa} in actuator coordinates and feedback control signal f_{ffa} in actuator coordinates are fed into a gain correction calculation device ⊖₂.

FIG. 7 shows a block scheme of the gain correction calculation device ⊖₂. The calculation of gain correction K in this scheme is as follows:

$$K = - Γ {f}_{fba} {f}_{ffa} ( t ) dt$$

wherein K is the actuator gain correction, f_{fba} the feedback control signal in actuator coordinates, and f_{ffa} a feedforward control signal in actuator coordinates.

The adaptive scheme of the actuator gain correction device of FIGS. 6 and 7 is based on the output of the feedback control device FBC, i.e. feedback control signal f_{fb}. This value can directly obtained from the feedback control device FBC. However, the presence of integral action of the PID controller of the feedback control device FBC in the feedback control signal f_{fb}, should be taken into account in this alternative embodiment.

In addition or as an alternative for the feedforward control signal f_{ffa} and the feedback control signal f_{fba}, parameters based on these values, such as filtered values, derivative values, integrated values, and/or combinations thereof, may be used to calculate the actuator gain correction K.

The actuator gain correction devices as shown in FIGS. 4 to 7 allow to take into account slow change in variables over time relevant for the behavior of the electromagnetic actuators without the need for recalibration for non-linearity correction. This prevents the need for a significant amount of time normally required for recalibration.

The control scheme with actuator gain correction device may also allow for higher mirror accelerations, for example when source power increases.

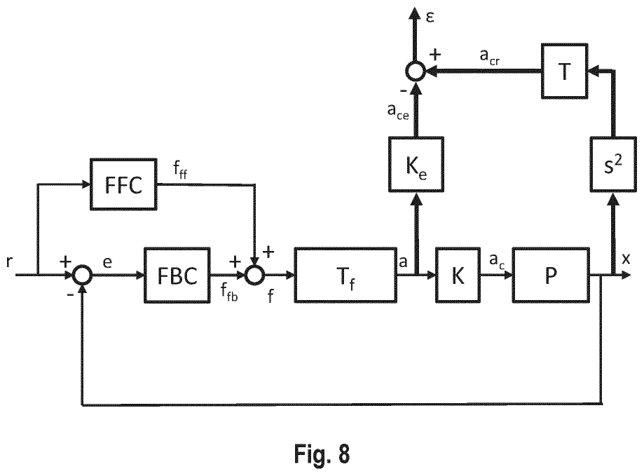

FIG. 8 shows another embodiment of a control scheme having an actuator gain correction device. The main control scheme corresponds substantially to the control scheme of FIG. 3 with the addition of the actuator gain correction K. This actuator gain correction K is applied to the actuator input a to obtain the corrected actuator input a_{c}.

In the actuator gain correction device of this control scheme, the gain correction K is determined on the basis of the actuator input a and the actual position x of the first mirror 13.

The actuator gain correction device is arranged to reconstruct an actual corrected actuator input a_{c} on the basis of the actual position x of the first mirror 13.

$${a}_{cr} = T {s}^{2} x$$

wherein T is a transformation from actual position to actuator input and x is the actual position of the first mirror 13.

This reconstructed actual corrected input a_{cr} is compared with an estimated corrected actuator input aₑ, that may be obtained by applying an estimated actuator gain correction Kₑ on the actuator input a. The comparison of a_{cr} with aₑ results in a difference between the reconstructed actual corrected input a_{cr} and the estimated corrected actuator input aₑ. This difference is the estimation error ε.

A recursive least-squares method may be used to calculate an estimate of the estimated actuator gain correction Kₑ and this estimated actuator gain correction Kₑ can be used as actuator gain correction K in the actual control loop. The estimated actuator gain correction Kₑ may be constantly updated on the basis of the estimation error E at time t and the estimated actuator gain correction Kₑ at time t−1.

Hereinabove, different embodiments are described in which an actuator gain correction is determined on the basis of at least one control value. In the embodiment of FIG. 4, the actuator gain correction is determined on the basis of the position control error e and the feedforward control signal f_{ff}. In the embodiment of FIG. 6, the actuator gain correction is determined on the basis of the feedback control signal f_{fb} and the feedforward control signal f_{ff}. In the embodiment of FIG. 8, the actuator gain correction is determined on the basis of the actuator input a and the actual position x. In other embodiments, other control values, i.e. other values that are presently available in the control system may be used to determine the actuator gain correction which is applied to the actuator input a to obtain a corrected actuator input a_{c}. These control values for example include the desired position r, the position control error e, the feedforward control signal f_{ff}, feedback control signal f_{fb}, the control signal f, the actuator input a, the corrected actuator input a_{c} and the actual position x.

Hereinabove, a position control system to control a position of a mirror of a projection system in six degrees of freedom has been described. The position control system may also be used to control the position of other objects positioned with at least one electromagnetic actuator in multiple degrees of freedom, for example in a control system having six or more electromagnetic actuators to position the object in six degrees of freedom. Such object is for example a substrate support or a patterning device support.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set-out as in the following numbered clauses.
1. A control method for controlling a position of an object with an electromagnetic actuator, the method comprising:
   determining a position control error between a desired position and an actual position of the object,
   determining a feedback control signal based on the position control error,
   determining a feedforward control signal based on the desired position,
   combining the feedback control signal and the feedforward control signal into an actuator input,
   determining an actuator gain correction based on the actuator input and the actual position of the object,
   applying the actuator gain correction to the actuator input to provide a corrected actuator input, and
   feeding the corrected actuator input to the electromagnetic actuator to exert an actuator force on the object.
2. The control method of clause 1, wherein combining the feedback control signal and the feedforward control signal into the actuator input comprises decoupling steps.
3. The control method of clause 1 or 2, wherein determining the actuator gain correction is based on the feedforward control signal and on the position control error or the feedback control signal.
4. The control method of any of the preceding clauses, wherein the actuator gain correction is determined as:

$$K = - Γ \int ( p\_ 11 e\_a ( t ) + p\_ 12 ( de\_a ( t ) ) / dt ) ) f\_ffa ( t ) dt$$

wherein K is the actuator gain correction, p11 is a first constant, ea is a position control error in actuator coordinates, p12 is a second constant, and fffa a feedforward control signal in actuator coordinates.
5. The control method of clause 4, wherein the position control error in actuator coordinates is determined as:

$$ea = Te \cdot e ,$$

wherein Te is a position transformation matrix from object position coordinates to actuator coordinates, and e is the position control error.
6. The control method of clause 4 or 5, wherein the feedforward control signal in actuator coordinates is determined as:

$$fffa - Tfgc \cdot fff ,$$

wherein Tfgc is a transformation matrix from feedforward force in control coordinates to actuator coordinates, and fff is the feedforward control signal.
7. The control method of clause 6, wherein combining the feedback control signal and the feedforward control signal into the actuator input comprises decoupling steps and wherein Tfgc corresponds to the decoupling steps.
8. The control method of any of the clauses 4-7, wherein determining the feedback control signal is based on a proportional control constant and a derivative control constant, wherein p11 is substantially equal to the proportional control constant and p12 is substantially equal to the derivative control constant.
9. The control method of any of the clauses 1 or 2, wherein the method comprises:
reconstructing an actual corrected actuator input on the basis of the actual position of the object, and estimating the actuator gain correction on the basis of a difference between the actuator input and the corrected actuator input.
10. The control method of any of the clauses 1-9, wherein the method is arranged to control the position of the object in six degrees of freedom.
11. The control method of any of the clauses 1-10, wherein the object is an optical element of a projection system of a lithographic apparatus.
12. A control system to control the position of an object, wherein the control system comprises:
   an electromagnetic actuator arranged to exert an actuator force on the object based on an actuator input,
   a feedback control device arranged to provide a feedback control signal based on a position control error between a desired position and an actual position of the object,
   a feedforward control device arranged to provide a feedforward control signal based on the desired position,
wherein the control system is arranged to combine the feedback control signal and the feedforward control signal into an actuator input,
wherein the control system comprises an actuator gain correction device, wherein the actuator gain correction device is arranged to determine an actuator gain correction on the basis of the actuator input and the actual position of the object, and arranged to apply the actuator gain correction to the actuator input to provide a corrected actuator input to the electromagnetic actuator.
13. The control system of clause 12, wherein the control system comprises a decoupling device to apply decoupling steps to the combined feedback control signal and feedforward control signal.
14. The control system of clause 12 or 13, based on the feedforward control signal and on the position control error or the feedback control signal.
15. The control system of any of the clauses 12-14, wherein the actuator gain correction device is arranged to determine the actuator gain correction as:

$$K = - Γ \int ( p\_ 11 e\_a ( t ) + p\_ 12 ( de\_a ( t ) ) / dt ) ) f\_ffa ( t ) dt$$

wherein K is the actuator gain correction, p11 is a first constant, ea is a position control error in actuator coordinates, p12 is a second constant, and fffa a feedforward control signal in actuator coordinates.
16. The control system of clause 15, wherein the actuator gain correction device is arranged to determine the position error in actuator coordinates as:

$$ea = Te \cdot e ,$$

wherein Te is a position transformation matrix from object position coordinates to actuator coordinates, and e is the position control error.
17. The control system of clause 15 or 16, wherein the actuator gain correction device is arranged to determine the feedforward control signal in actuator coordinates as:

$$fffa - Tfgc \cdot fff ,$$

wherein Tfgc is a force transformation matrix from feedforward force in control coordinates to actuator coordinates, and Fff is the feedforward control signal.
18. The control system of clause 17, wherein combining the feedback control signal and the feedforward control signal into the actuator input comprises decoupling steps and wherein Tfgc corresponds to the decoupling steps.
19. The control system of any of the clauses 15-18, wherein the feedback control device comprises a proportional control constant and a derivative control constant, wherein p11 is substantially equal to the proportional control constant and p12 is substantially equal to the derivative control constant.
20. The control system of clause 12 or 13, wherein the actuator gain correction device is arranged to: reconstruct an actual corrected actuator input on the basis of the actual position of the object, and estimate the actuator gain correction on the basis of a difference between the actuator input and the corrected actuator input.
21. The control system of any of the clauses 12-20, wherein the control system is arranged to control the position of the object in six degrees of freedom.
22. The control system of any of the clauses 12-21, wherein the control system comprises a position measurement system to determine the actual position of the object.
23. A lithographic apparatus comprising a control system as according to any of the clauses 12-22 to control the position of an object of the lithographic apparatus.
24. The lithographic apparatus of clause 23, wherein the object is an optical element of the lithographic apparatus.
25. The lithographic apparatus of clause 23 or 24, wherein the object is a mirror of a projection system of the lithographic apparatus.

1-25. (canceled)

26. A control method for controlling a position of an object with an electromagnetic actuator, the method comprising:
determining a position control error between a desired position and an actual position of the object;
determining a feedback control signal based on the position control error;
determining a feedforward control signal based on the desired position;
combining the feedback control signal and the feedforward control signal into an actuator input;
determining an actuator gain correction based on the actuator input and the actual position of the object;
applying the actuator gain correction to the actuator input to provide a corrected actuator input; and
feeding the corrected actuator input to the electromagnetic actuator to exert an actuator force on the object.

27. The control method of claim 26, wherein the combining the feedback control signal and the feedforward control signal into the actuator input comprises decoupling.

28. The control method of claim 26, wherein the determining the actuator gain correction is based on the feedforward control signal and on the position control error or the feedback control signal.

29. The control method of claim 26, wherein the actuator gain correction is determined as:
$$K = - Γ \int ( {p}_{11} {e}_{a} ( t ) + {p}_{12} \frac{{de}_{a} ( t )}{dt} ) {f}_{ffa} ( t ) dt$$
wherein K is the actuator gain correction, p₁₁ is a first constant, eₐ is a position control error in actuator coordinates, p₁₂ is a second constant, and f_{ffa} is a feedforward control signal in actuator coordinates.

30. The control method of claim 29, wherein the position control error in actuator coordinates is determined as:
$${e}_{a} = {T}_{e} \cdot e ,$$
wherein Tₑ is a position transformation matrix from object position coordinates to actuator coordinates, and e is the position control error.

31. The control method of claim 29, wherein the feedforward control signal in actuator coordinates is determined as:
$${f}_{ffa} = {T}_{fgc} \cdot {f}_{ff} ,$$
wherein T_{fgc} is a transformation matrix from feedforward force in control coordinates to actuator coordinates, and f_{ff} is the feedforward control signal.

32. The control method of claim 31, wherein:
the combining the feedback control signal and the feedforward control signal into the actuator input comprises decoupling, and
T_{fgc} corresponds to the decoupling.

33. The control method of claim 29, wherein:
the determining the feedback control signal is based on a proportional control constant and a derivative control constant,
p₁₁ is substantially equal to the proportional control constant, and
p₁₂ is substantially equal to the derivative control constant.

34. A control system to control a position of an object, wherein the control system comprises:
an electromagnetic actuator arranged to exert an actuator force on the object based on an actuator input;
a feedback control device arranged to provide a feedback control signal based on a position control error between a desired position and an actual position of the object;
an actuator gain correction device; and
a feedforward control device arranged to provide a feedforward control signal based on the desired position,
wherein the control system is arranged to combine the feedback control signal and the feedforward control signal into an actuator input,
wherein the actuator gain correction device is arranged to determine an actuator gain correction based on the actuator input and the actual position of the object, and arranged to apply the actuator gain correction to the actuator input to provide a corrected actuator input to the electromagnetic actuator.

35. The control system of claim 34, wherein the control system comprises a decoupling device that is configured to apply decoupling to the combined feedback control signal and feedforward control signal.

36. The control system of claim 35, wherein the decoupling is based on the feedforward control signal and on the position control error or the feedback control signal.

37. The control system of claim 34, wherein the actuator gain correction device is arranged to determine the actuator gain correction as:
$$K = - Γ \int ( {p}_{11} {e}_{a} ( t ) + {p}_{12} \frac{{de}_{a} ( t )}{dt} ) {f}_{ffa} ( t ) dt$$
wherein K is the actuator gain correction, p₁₁ is a first constant, eₐ is a position control error in actuator coordinates, p₁₂ is a second constant, and f_{ffa} is a feedforward control signal in actuator coordinates.

38. The control system of claim 37, wherein the actuator gain correction device is arranged to determine the position error in actuator coordinates as:
$${e}_{a} = {T}_{e} \cdot e ,$$
wherein Tₑ is a position transformation matrix from object position coordinates to actuator coordinates, and e is the position control error.

39. The control system of claim 37, wherein the actuator gain correction device is arranged to determine the feedforward control signal in actuator coordinates as:
$${f}_{ffa} = {T}_{fgc} \cdot {f}_{ff} ,$$
wherein T_{fgc} is a force transformation matrix from feedforward force in control coordinates to actuator coordinates, and f_{ff} is the feedforward control signal.

40. The control system of claim 39, wherein:
the combining the feedback control signal and the feedforward control signal into the actuator input comprises decoupling, and
T_{fgc} corresponds to the decoupling.

41. The control system of claim 37, wherein:
the feedback control device comprises a proportional control constant and a derivative control constant,
p₁₁ is substantially equal to the proportional control constant, and
p₁₂ is substantially equal to the derivative control constant.

42. The control system of claim 34, wherein the actuator gain correction device is arranged to:
reconstruct an actual corrected actuator input based on the actual position of the object, and
estimate the actuator gain correction based on a difference between the actuator input and the corrected actuator input.

43. A lithographic apparatus comprising:
the control system of claim 34 configured to control the position of the object of the lithographic apparatus.

44. The lithographic apparatus of claim 43, wherein the object is an optical element of the lithographic apparatus.

45. The lithographic apparatus of claim 43, further comprising a projection system comprising a mirror, wherein the object is the mirror of the projection system.
